(19) United States
(12) Patent Application Publication
(10) Pub. No.: US 2025/0323604 A1
(43) Pub. Date: Oct. 16, 2025

(54) AUDIO SIGNAL CONVERTER DEVICE AND AMPLIFIER THEREOF

(71) Applicant: SigmaStar Technology Ltd., Xiamen (CN)

(72) Inventors: Chunbin LI, Shanghai (CN); Zhun CHEN, Shanghai (CN)

(21) Appl. No.: 18/983,790

(22) Filed: Dec. 17, 2024

(30) Foreign Application Priority Data
Apr. 11, 2024 (CN) 202410437610.1

(51) Int. Cl. H03F 1/26; H03G 3/30

(52) U.S. Cl. CPC H03F 1/26; H03G 3/3005; H03F 2200/03; H03F 2200/171; H03G 2201/103

(57) ABSTRACT

An audio signal converter device includes a variable gain amplifier circuit, a loop filter circuit, a quantizer circuit, and a digital-to-analog converter circuit. The variable gain amplifier circuit amplifies an audio signal to generate multiple first signals. The loop filter circuit generates multiple second signals according to the first signals. The quantizer circuit generates a digital output according to the second signals. The digital-to-analog converter circuit adjusts the first signals according to the digital output. A corresponding circuit in the variable gain amplifier circuit or the loop filter circuit includes an amplifier, which includes an input pair circuit and a load circuit The input pair circuit includes multiple input terminals and output terminals. The load circuit includes multiple transistors and a chopper circuit. The chopper circuit is coupled to the output terminals via the transistors and performs a noise modulation according to a clock signal.

This application claims the benefit of China application Serial No. CN 202410437610.1, filed on Apr. 11, 2024, the subject matter of which is incorporated herein by reference.

### BACKGROUND OF THE INVENTION

### Field of the Invention

The present application relates to an audio processing device, and more particularly to an audio signal converter device capable of reducing influences of noise and an amplifier thereof.

### Description of the Related Art

In the prior art, an audio processing device often uses an amplifier to amplify audio signals for proceeding of subsequent signal processing. However, an amplifier in fact contains circuit noise (for example, including such as flicker noise and thermal noise). If left unprocessed, such noise affects a noise-to-signal ratio (SNR) of an audio processing device and degrades quality of signals output by the audio processing device.

### SUMMARY OF THE INVENTION

In some embodiments, it is an object of the present application to provide an audio signal converter device capable of reducing influences of noise and an amplifier thereof so as to improve the issues of the prior art.

In some embodiments, the audio signal converter device includes a variable gain amplifier circuit, a loop filter circuit, a quantizer circuit, and a digital-to-analog converter circuit. The variable gain amplifier circuit amplifies an audio signal to generate a plurality of first signals. The loop filter circuit generates a plurality of second signals according to the plurality of first signals. The quantizer circuit generates a digital output according to the plurality of second signals. The digital-to-analog converter circuit adjusts the plurality of first signals according to the digital output. The variable gain amplifier circuit includes an amplifier, which includes an input pair circuit and a load circuit. The input pair circuit includes a plurality of input terminals and a plurality of output terminals. The plurality of input terminals receive the audio signal, and the plurality of output terminals output a plurality of third signals associated with the plurality of first signals. The load circuit includes a plurality of transistors and a chopper circuit. The chopper circuit is coupled to the plurality of output terminals via the plurality of transistors, and performs a noise modulation according to a first clock signal.

In some embodiments, the audio signal converter device includes a variable gain amplifier circuit, a loop filter circuit, a quantizer circuit, and a digital-to-analog converter circuit. The variable gain amplifier circuit amplifies an audio signal to generate a plurality of first signals. The loop filter circuit generates a plurality of second signals according to the plurality of first signals. The quantizer circuit generates a digital output according to the plurality of second signals. The digital-to-analog converter circuit adjusts the plurality of first signals according to the digital output. The loop filter circuit includes an amplifier, which includes an input pair circuit and a load circuit. The input pair circuit includes a plurality of input terminals and a plurality of output terminals. The plurality of input terminals receive the plurality of first signals, and the plurality of output terminals output a plurality of third signals associated with the plurality of second signals. The load circuit includes a plurality of transistors and a chopper circuit. The chopper circuit is coupled to the plurality of output terminals via the plurality of transistors, and performs a noise modulation according to a first clock signal.

In some embodiments, the amplifier includes an input pair circuit and a load circuit. The input pair circuit includes a plurality of input terminals and a plurality of output terminals. The load circuit includes a plurality of transistors and a chopper circuit. The chopper circuit is coupled to the plurality of output terminals via the plurality of transistors and performs a noise modulation according to a clock signal.

Features, implementations and effects of the present application are described in detail in preferred embodiments with the accompanying drawings below.

### BRIEF DESCRIPTION OF THE DRAWINGS

To better describe the technical solution of the embodiments of the present application, drawings involved in the description of the embodiments are introduced below. It is apparent that, the drawings in the description below represent merely some embodiments of the present application, and other drawings apart from these drawings may also be obtained by a person skilled in the art without involving inventive skills.

FIG. 1 is a schematic diagram of an audio signal converter device according to some embodiments of the present application;

FIG. 2A is a schematic diagram of an amplifier circuit according to some embodiments of the present application;

FIG. 2B is a schematic diagram of the input-stage circuit in FIG. 2A according to some embodiments of the present application; and

FIG. 3 is a schematic diagram of a noise modulation of a noise modulation circuit in FIG. 2B according to some embodiments of the present application.

### DETAILED DESCRIPTION OF THE INVENTION

All terms used in the literature have commonly recognized meanings. Definitions of the terms in commonly used dictionaries and examples discussed in the disclosure of the present application are merely exemplary, and are not to be construed as limitations to the scope or the meanings of the present application. Similarly, the present application is not limited to the embodiments enumerated in the description of the application.

The term “coupled” or “connected” used in the literature refers to two or multiple elements being directly and physically or electrically in contact with each other, or indirectly and physically or electrically in contact with each other, and may also refer to two or more elements operating or acting with each other. As given in the literature, the term “circuit” may be a device connected by at least one transistor and/or at least one active element by a predetermined means so as to process signals.

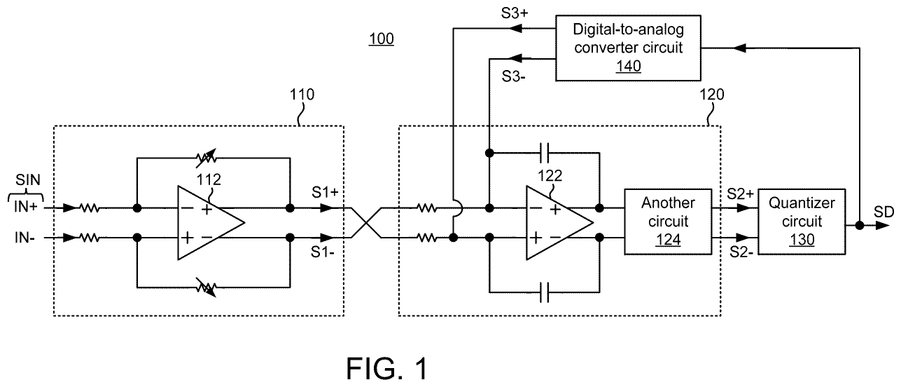

FIG. 1 shows a schematic diagram of an audio signal converter device 100 according to some embodiments of the present application. The audio signal converter device 100 includes a variable gain amplifier circuit 110, a loop filter circuit 120, a quantizer circuit 130, and a digital-to-analog converter circuit 140. The variable gain amplifier circuit 110 may amplify an audio signal SIN (including, for example, differential signals IN+ and IN−) to generate a signal S1+ and a signal S1−. In some embodiments, the loop filter circuit 120, the quantizer circuit 130 and the digital-to-analog converter circuit 140 form a continuous-time sigma-delta modulation analog-to-digital converter, which may generate a corresponding digital output SD according to the signal S1+ and the signal S1−.

More specifically, the loop filter circuit 120 may generate a signal S2+ and a signal S2− according to the signal S1+ and the signal S1−. The quantizer circuit 130 may generate the digital output SD according to the signal S2+ and the signal S2−. The digital-to-analog converter circuit 140 generates a signal S3+ and a signal S3− according to the digital output SD to adjust the signal S1+ and the signal S1−. In some embodiments, the loop filter circuit 120 may be used to reduce noise on the signal S1+ and the signal S1− to generate the signal S2+ and the signal S2−. In some embodiments, the quantizer circuit 130 may be implemented by, for example but not limited to, a comparator circuit. In some embodiments, the digital-to-analog converter circuit 140 may be, for example but not limited to, a resistive digital-to-analog converter circuit, which may generate the corresponding signals S3+ and S3− (which may be current signals) according to the digital output, and transmit the signal S3+ and the signal S3− to multiple input terminals of the loop filter circuit 120 to thereby adjust levels of the signal S2+ and the signal S2−.

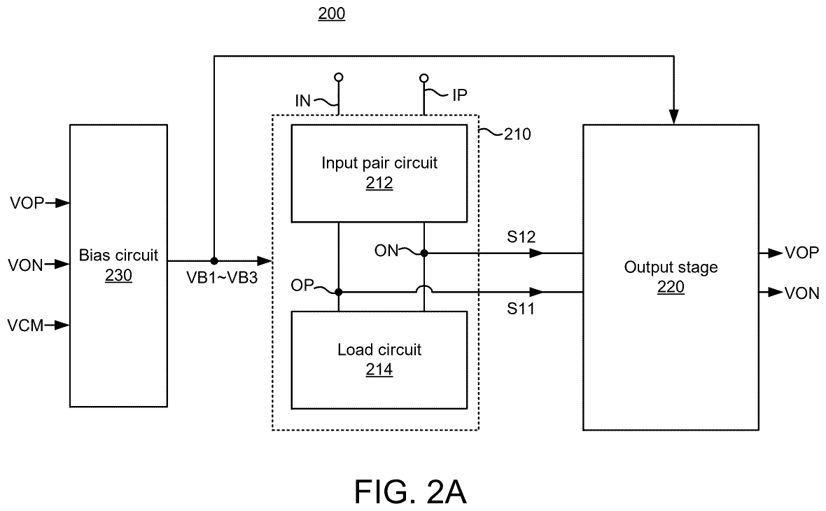

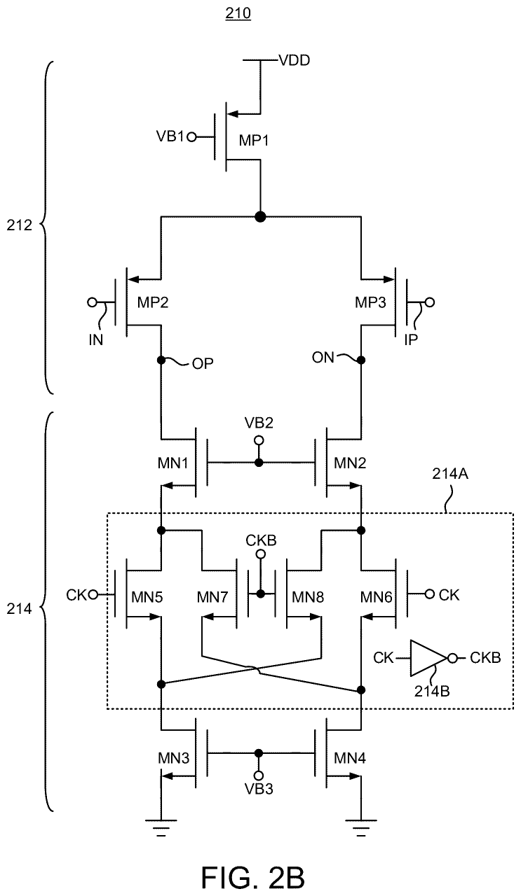

As shown in FIG. 1, the variable gain amplifier circuit 110 includes an amplifier 112 and a negative feedback network (for example, multiple resistors connected to the amplifier 122 in FIG. 1). The negative feedback network may be used to set the gain of the amplifier 112 to thereby adjust an overall amplification gain of the variable gain amplifier circuit 110. Similarly, the loop filter circuit 120 includes an amplifier 122, a negative feedback network (for example, multiple resistors and capacitors connected to the amplifier 122 in FIG. 2), and another circuit 124. The amplifier 122 and the negative feedback network may form a resistor-capacitor integrator. In some embodiments, the another circuit 124 may include other passive elements, is coupled to an output of the resistor-capacitor integrator to adjust a bandwidth of the resistor-capacitor integrator, and generates the signal S2+ and the signal S2− according to an output of the amplifier 122; however, the present application is not limited to the examples above.

In some embodiments, by performing equivalent input noise analysis on the variable gain amplifier circuit 110, it can be deduced that internal noise of the amplifier 112 is amplified to four times when the gain of the variable gain amplifier circuit 110 is set to 0 decibel. Similarly, by performing equivalent input noise analysis on the resistor-capacitor integrator above, it can be deduced that internal noise of the amplifier 122 is amplified to four times when the gain of the resistor-capacitor integrator is set to 0 decibel. Hence, it is known that, if the internal noise of the amplifier 112 and/or the amplifier 122 can be reduced, noticeable benefits can be brought upon the signal quality and the overall performance of the audio signal converter device 100. Thus, in a different embodiment, at least one corresponding circuit in the amplifier 112 and the amplifier 122 may be implemented by an amplifier 200 in an embodiment to be described below. The amplifier 200 has a chopping technique for noise modulation on internal noise thereof, so as to reduce influences of noise upon audio signals.

FIG. 2A shows a schematic diagram of the amplifier circuit 200 according to some embodiments of the present application. The amplifier 200 includes an input stage 210, an output stage 220 and a bias circuit 230. The input stage 210 includes an input pair circuit 212 and a load circuit 214. The input pair circuit 212 includes an input terminal IN, an input terminal IP, an output terminal ON and an output terminal OP. If the amplifier 112 in FIG. 1 is implemented by the amplifier 200, the input terminal IP and the input terminal IN may be used to respectively receive the signal IN+ and the signal IN− (that is, the audio signal SIN) in FIG. 1, and the output terminal OP and the output terminal ON may be used to respectively output a signal S11 and a signal S12 (which may be, for example, related signals for generating the signal S1+ and the signal S1−) associated with the signal S1+ and the signal S1− in FIG. 1. Similarly, if the amplifier 122 in FIG. 1 is implemented by the amplifier 200, the input terminal IP and the input terminal IN may be used to respectively receive the signal S1+ and the signal S1− in FIG. 1 via two resistors in the loop filter circuit 120, and the output terminal OP and the output terminal ON may be used to respectively output the signal S11 and the signal S12 (which may be, for example, related signals for generating the signal S2+ and the signal S2−) associated with the signal S2+ and the signal S2− in FIG. 1. The input pair circuit 212 may generate the signal S11 and the signal S12 according to the signals received from the input terminal IN and the input terminal IP, and transmit the signal S11 and the signal S12 to the output stage 220 via the output terminal OP and the output terminal ON. The load circuit 214 is coupled to the output terminal ON and the output terminal OP, and operates as an active load of the input pair circuit 212 to increase an amplification gain of the input stage 210. The output stage 220 amplifies the signal S11 and the signal S12 to generate a signal VON and a signal VOP having larger swings. In some embodiments, the output stage 220 may further include a circuit part (for example but not limited to, a resistor-capacitor network) used for frequency compensation.

If the amplifier 112 in FIG. 1 is implemented by the amplifier 200, the signal VON and the signal VOP may be the signal S1+ and the signal S1− in FIG. 1. Alternatively, if the amplifier 122 in FIG. 1 is implemented by the amplifier 200, the signal VON and the signal VOP may be outputs of the amplifier 122 The bias circuit 230 is for providing a bias voltage needed by the input stage 210 and/or the output stage 220. For example, the bias circuit 230 may include one or more current mirror circuits which may generate voltages VB1, VB2 and VB3 to thereby bias the input stage 210 and/or the output stage 220. On the other hand, the bias circuit 230 further includes a common-mode feedback circuit, which may adjust common-mode levels of the signal VON and the signal VOP according to the signal VON, the signal VOP and a predetermined common-mode voltage VCM of the two.

FIG. 2B shows a schematic diagram of the input-stage circuit 210 in FIG. 2A according to some embodiments of the present application. In some embodiments, the input pair circuit 212 includes a transistor MP1, a transistor MP2 and a transistor MP3. The transistor MP1 operates as a current source according to the voltage VB1 to bias the transistor MP2 and the transistor MP3. More specifically, a first terminal (for example, the source) of the transistor MP1 receives a voltage VDD, a second terminal (for example, the drain) of the transistor MP1 is coupled to a first terminal of the transistor MP2 and a first terminal of the transistor MP3, and a control terminal (for example, the gate) of the transistor MP1 receives the voltage VB1. A control terminal of the transistor MP2 is coupled to the input terminal IN, and a second terminal of the transistor MP2 is coupled to the output terminal OP. A control terminal of the transistor MP3 is coupled to the input terminal IP, and a second terminal of the transistor MP3 is coupled to the output terminal ON.

The load circuit 214 includes multiple transistors MN1 to MN4 and a chopper circuit 214A. The chopper circuit 214A is coupled to the output terminal ON and the output terminal OP via the multiple transistors MN1 and the transistor MN2, and may perform a noise modulation according to a clock signal CK. In other words, the chopper circuit 214A is not directly connected to the output terminal ON or the output terminal OP. The noise modulation performed by the chopper circuit 214A is achieved by quickly switching a switch. Since the chopper circuit 214A is not directly connected to the output terminal ON or the output terminal OP, influences of signal jitter resulted from quickly switching the switch above upon the output terminal ON and the output terminal OP can be mitigated, so as to reduce noise induced by the chopper circuit 214A into the output terminal OP and the output terminal ON.

More specifically, the chopper circuit 214A may include multiple transistors MN5 to MN8. A first terminal (for example, the drain) of the transistor MN1 is coupled to the output terminal OP, a second terminal (for example, the source) of the transistor MN1 is coupled to a first terminal of the transistor MN5 and a first terminal of the transistor MN7, and a control terminal (for example, the gate) of the transistor MN1 receives the voltage VB2. A first terminal of the transistor MN2 is coupled to the output terminal ON, a second terminal of the transistor MN2 is coupled to a first terminal of the transistor MN6 and a first terminal of the transistor MN8, and a control terminal of the transistor MN2 receives the voltage VB2. A first terminal of the transistor MN3 is coupled to a second terminal of the transistor MN5 and a second terminal of the transistor MN8, a second terminal of the transistor MN3 is grounded, and a control terminal of the transistor MN3 receives the voltage VB3. A first terminal of the transistor MN4 is coupled to a second terminal of the transistor MN6 and a second terminal of the transistor MN7, a second terminal of the transistor MN4 is grounded, and a control terminal of the transistor MN4 receives the voltage VB3. A control terminal of the transistor MN5 and a control terminal of the transistor MN6 receive the clock signal CK, and a control terminal of the transistor MN7 and a control terminal of the transistor MN8 receive a clock signal CKB, wherein the clock signal CKB is a logically inverted signal of the clock signal CK. In some embodiments, the chopper circuit 214A may further include an inverter 214B, which may generate the clock signal CKB according to the clock signal CK.

In other words, the transistor MN5 is coupled between the transistor MN1 and the transistor MN3, the transistor MN6 is coupled between the transistor MN2 and the transistor MN4, the transistor MN7 is coupled between the transistor MN1 and the transistor MN4, and the transistor MN8 is coupled between the transistor MN2 and the transistor MN3. Thus, the transistor MN5 and the transistor MN7 may be coupled to the output terminal OP via the transistor MN1, and the transistor MN6 and the transistor MN8 may be coupled to the output terminal ON via the transistor MN2. The transistor MN1 and the transistor MN2 are biased by the voltage VB2, and the transistor MN3 and the transistor MN4 VB3 are biased by the voltage VB3. The transistor MN5 and the transistor MN6 are selectively turned on according to the clock signal CK, and the transistor MN7 and the transistor MN8 are selectively turned on according to the clock signal CKB. The transistor MN5 and the transistor MN7 are alternately turned on, and the transistor MN6 and the transistor MN8 are alternately turned on. For example, when the transistor MN5 and the transistor MN6 are turned on, the transistor MN7 and the transistor MN8 are turned off, and vice versa.

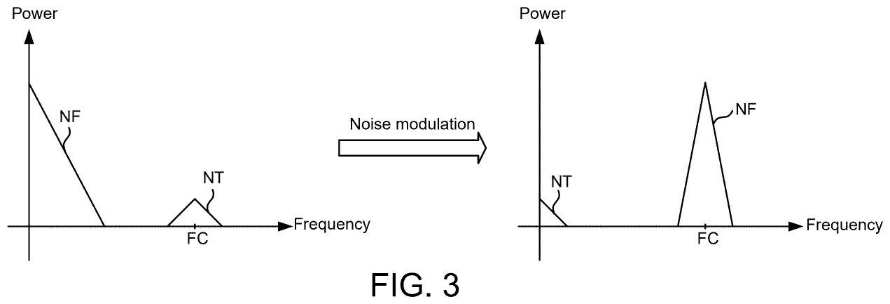

With the configuration above, the chopper circuit 214A may be not directly connected to the output terminal OP or the output terminal ON, and be coupled among the multiple transistors MN1 to MN4. Thus, a signal node of the chopper circuit 214A while the noise modulation is performed is associated with the multiple transistors MN1 to MN4 operating as an active load, such that the noise modulation performed by the chopper circuit 214A may shift the frequencies of noise on the multiple transistors MN1 to MN4 (to be described with reference to FIG. 3 below), thereby reducing influences of noise.

In some related art, an amplifier using a chopper technique performs a first round of modulation on an input signal received by an amplifier by a chopper circuit disposed on an input terminal to modulate the input signal to a high frequency, and performs a second round of modulation on an output signal generated by the amplifier by another chopper circuit disposed on an output terminal to demodulate the output signal. However, in FIG. 1, both of the amplifier 112 and the amplifier 122 are provided as a continuous-time signal processing circuit, and if processing is performed by a chopper circuit at both the input terminal and the output terminal of the amplifier, signal jitter generated may be too large such that it is possible that other noise be introduced into the overall system. Moreover, since the amplifier 122 is configured as a sigma-delta modulation analog-to-digital converter, the input terminal of the amplifier 122 in fact further receives quantization noise. If chopping modulation is performed on the input terminal of the amplifier 122, such quantization noise is inevitably mixed and added into a signal band to be processed. Thus, compared to the technique above, in some embodiments of the present application, the signals (for example, the audio signal SIN, or the signals S1+ and S1−) received by the input terminal IN and the input terminal IP do not undergo any processing by another chopper circuit. That is, compared to the above technique that uses two chopper circuits to perform two rounds of noise modulation, the amplifier 200 merely uses one chopper circuit 214A to perform the noise modulation (that is, in some embodiments, the number of chopper circuit in the amplifier 200 is only one), the chopper circuit 214A is not directly connected to the output terminal OP or the output terminal ON of the amplifier 200, and none of the input terminal IP, the input terminal IN, the output terminal OP and the output terminal ON of the amplifier 200 is directly connected another chopper circuit. Thus, influences of signal jitter brought upon the output terminal OP and the output terminal ON can be reduced to prevent the above quantization noise from being mixed or added.

FIG. 3 shows a schematic diagram of the noise modulation of the noise modulation circuit 214A in FIG. 2B according to some embodiments of the present application. As shown in FIG. 3, before the noise modulation, in the load circuit 214, noise NF (which may be, for example, flicker noise in a circuit) having a high power is located at a low band, and noise NT (which may be, for example, thermal noise) having a lower power is located at a higher frequency FC (which is the frequency of the clock signal CK). After the noise modulation, the noise NT is relocated to the low band, and the noise NF is relocated to the frequency FC. Thus, with the noise modulation, the noise NT having a lower power can be moved to a low band (which is where main signals are) to thereby reduce the overall noise.

In some embodiments, the frequency FC of the clock signal CK may be defined on the basis of a hearing frequency range of the human ear. For example, the hearing frequency range of the human ear ranges between about 20 and 20000 Hz. The frequency FC may be configured to be higher than this hearing frequency range of the human ear, that is, higher than 20000 Hz. Thus, the noise NT is modulated to locate outside the hearing frequency range of the human ear, so as to reduce influences thereof upon audio signals. In some embodiments, the frequency FC may be set as a sampling rate used by the sigma-delta modulation analog-to-digital converter above; however, the present application is not limited the example above.

In conclusion, the audio signal converter device and the amplifier thereof according to some embodiments of the present application are capable of performing one round of noise modulation by using a chopper circuit to thereby reduce the overall noise. Wherein, the chopper circuit is not directly connected to the output terminal of the amplifier, so that influences of signal jitter in the noise modulation brought upon the output terminal can be reduced.

While the present application has been described by way of example and in terms of the preferred embodiments, it is to be understood that the disclosure is not limited thereto. Various modifications may be made to the technical features of the present application by a person skilled in the art on the basis of the explicit or implicit disclosures of the present application. The scope of the appended claims of the present application therefore should be accorded with the broadest interpretation so as to encompass all such modifications.

What is claimed is:

1. An audio signal converter device, comprising:
a variable gain amplifier circuit, amplifying an audio signal to generate a plurality of first signals;
a loop filter circuit, generating a plurality of second signals according to the plurality of first signals;
a quantizer circuit, generating a digital output according to the plurality of second signals; and
a digital-to-analog converter circuit, adjusting the plurality of first signals according to the digital output,
wherein the variable gain amplifier circuit comprises an amplifier comprising:
an input pair circuit, comprising a plurality of input terminals and a plurality of output terminals, the plurality of input terminals receiving the audio signals, the plurality of output terminals outputting a plurality of third signals associated with the plurality of first signals; and
a load circuit, comprising a plurality of transistors and a chopper circuit, the chopper circuit coupled to the plurality of output terminals via the plurality of transistors and performing a noise modulation according to a first clock signal.

2. The audio signal converter device according to claim 1, wherein the chopper circuit is not directly connected to the plurality of output terminals.

3. The audio signal converter device according to claim 1, wherein a frequency of the first clock signal is higher than a hearing frequency range of human ear.

4. The audio signal converter device according to claim 1, wherein a quantity of the chopper circuit in the variable gain amplifier circuit is only one.

5. The audio signal converter device according to claim 1, wherein the chopper circuit is coupled among a plurality of transistors.

6. The audio signal converter device according to claim 1, wherein the plurality of transistors comprise:
a first transistor, coupled to a first output terminal of the plurality of output terminals, and biased by a first voltage;
a second transistor, coupled to a second output terminal of the plurality of output terminals, and biased by the first voltage;
a third transistor, coupled to the first transistor via the chopper circuit, and biased by a second voltage; and
a fourth transistor, coupled to the second transistor via the chopper circuit, and biased by the second voltage.

7. The audio signal converter device according to claim 6, wherein the chopper circuit comprises:
a fifth transistor, coupled between the first transistor and the third transistor, and selectively turned on according to the first clock signal;
a sixth transistor, coupled between the second transistor and the fourth transistor, and selectively turned on according to the first clock signal;
a seventh transistor, coupled between the first transistor and the fourth transistor, and selectively turned on according to a second clock signal; and
an eighth transistor, coupled between the second transistor and the third transistor, and selectively turned on according to the second clock signal, wherein the second clock signal is a logically inverted signal of the first clock signal.

8. The audio signal converter device according to claim 7, wherein the fifth transistor and the seventh transistor are alternately turned on, and the sixth transistor and the eighth transistor are alternately turned on.

9. An audio signal converter device, comprising:
a variable gain amplifier circuit, amplifying an audio signal to generate a plurality of first signals;
a loop filter circuit, generating a plurality of second signals according to the plurality of first signals;
a quantizer circuit, generating a digital output according to the plurality of second signals; and
a digital-to-analog converter circuit, adjusting the plurality of first signals according to the digital output,
wherein the loop filter circuit comprises an amplifier comprising:
an input pair circuit, comprising a plurality of input terminals and a plurality of output terminals, the plurality of input terminals receiving the plurality of first signals, and the plurality of output terminals outputting a plurality of third signals associated with the plurality of second signals; and
a load circuit, comprising a plurality of transistors and a chopper circuit, the chopper circuit coupled to the plurality of output terminals via the plurality of transistors and performing a noise modulation according to a first clock signal.

10. An amplifier, comprising:
an input pair circuit, comprising a plurality of input terminals and a plurality of output terminals; and
a load circuit, comprising a plurality of transistors and a chopper circuit, the chopper circuit coupled to the plurality of output terminals via the plurality of transistors and performing a noise modulation according to a clock signal.

11. The amplifier according to claim 10, wherein the plurality of input terminals or the plurality of output terminals are not directly connected to another chopper circuit.
